(19) United States
(12) Patent Application Publication
(10) Pub. No.: US 2023/0407424 A1
(43) Pub. Date: Dec. 21, 2023

(54) VACUUM HEAT TREATMENT APPARATUS

(71) Applicant: TOKYO ELECTRON LIMITED, TOKYO (JP)

(72) Inventor: Junichi TAKEI, Yamanashi (JP)

(21) Appl. No.: 18/329,372

(22) Filed: Jun. 5, 2023

(30) Foreign Application Priority Data
Jun. 16, 2022 (JP) 2022-097388

(51) Int. Cl. C21D 1/773; C23C 16/54; C23C 16/56; C21D 9/00

(52) U.S. Cl. CPC C21D 1/773; C23C 16/54; C23C 16/56; C21D 9/0018

(57) ABSTRACT

There is a vacuum heat treatment apparatus comprising: a vacuum chamber; a stage disposed in the vacuum chamber and having a substrate placing surface on which a substrate is placed; a heater provided in the stage; a partition member configured to partition a part of an internal space of the vacuum chamber to form a gas processing space between itself and the substrate placing surface of the stage; and a gas supply configured to supply gas to the gas processing space.

### CROSS-REFERENCE TO RELATED APPLICATIONS

This application claims priority to Japanese Patent Application No. 2022-097388, filed on Jun. 16, 2022, the entire contents of which are incorporated herein by reference.

### TECHNICAL FIELD

The present disclosure relates to a vacuum heat treatment apparatus.

### BACKGROUND

Patent Document 1 discloses a substrate accommodating unit provided in a substrate transfer apparatus in which a plurality of vacuum transfer units, each having therein a substrate transfer mechanism configured to hold and transfer a substrate, are arranged consecutively. The substrate accommodating unit is disposed adjacent to each of the vacuum transfer units in an arrangement direction of the vacuum transfer units. The substrate accommodating unit includes a hollow housing having, on one side wall in the arrangement direction of the vacuum transfer units, a loading/unloading port for loading and unloading the substrate into and from the adjacent vacuum transfer unit, a partition member disposed in the housing and configured to be vertically movable, and a driving mechanism configured to vertically move the partition member. When an inner space of the housing is vertically divided into a first space on the loading/unloading port side and a second space on an opposite side of the loading/unloading port side, the partition member is vertically moved from a state where the first space and the second space communicate with each other to thereby airtightly separate the first space and the second space with the partition member.

### PRIOR ART DOCUMENTS

### Patent Documents

Patent Document 1: Japanese Laid-open Patent Publication No. 2021-72424

### SUMMARY

In one aspect, the present disclosure provides a vacuum heat treatment apparatus that improves throughput.

In accordance with an aspect of the present disclosure, there is a vacuum heat treatment apparatus comprising: a vacuum chamber; a stage disposed in the vacuum chamber and having a substrate placing surface on which a substrate is placed; a heater provided in the stage; a partition member configured to partition a part of an internal space of the vacuum chamber to form a gas processing space between itself and the substrate placing surface of the stage; and a gas supply configured to supply gas to the gas processing space.

### BRIEF DESCRIPTION OF THE DRAWINGS

The objects and features of the present disclosure will become apparent from the following description of embodiments, given in conjunction with the accompanying drawings, in which:

FIG. 1 is an example of a cross-sectional view to illustrate an example configuration of a vacuum heat treatment apparatus;

FIG. 2 is an example of a bottom view of a partition member;

FIG. 3 is an example of a flow chart illustrating an operation of the vacuum heat treatment apparatus;

FIG. 4 is an example of a cross-sectional view of the vacuum heat treatment apparatus while substrate lift pins and partition member lift pins are being raised; and

FIG. 5 is an example of a cross-sectional view of the vacuum heat treatment apparatus after the substrate lift pins and the partition member lift pins have finished rising.

### DETAILED DESCRIPTION

Hereinafter, embodiments for carrying out the present disclosure will be described with reference to the accompanying drawings. In each drawing, the same components are identified by the same reference numerals, and redundant description may be omitted.

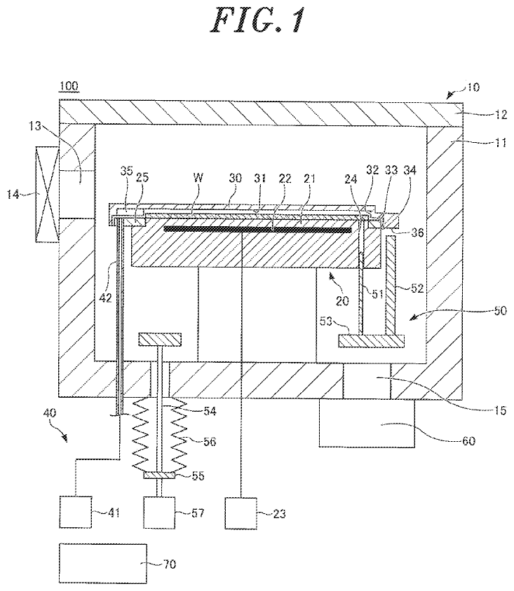

A vacuum heat treatment apparatus 100 will be described with reference to FIG. 1. FIG. 1 is an example of a cross-sectional view to illustrate an example configuration of the vacuum heat treatment apparatus 100. Here, the vacuum heat treatment apparatus 100 is an apparatus (also referred to as a degassing apparatus) for sublimating and removing an object to be removed (e.g., a film (e.g., an organic film) formed in a previous step) from a surface of a substrate W by heating the substrate W in a vacuum chamber 10 and supplying an inert gas to a gas processing space in which the substrate W is disposed to a high pressure (e.g., 5 to 20 Torr).

The vacuum heat treatment apparatus 100 includes the vacuum chamber 10, a placing section 20, a partition member a gas supply 40, a vertical driving mechanism 50, an exhaust device 60, and a controller 70.

The vacuum chamber 10 has a vacuum chamber main body 11 and a lid 12. The vacuum chamber main body 11 is made of a metal material such as aluminum and has a substantially cylindrical shape with an open top and a bottom. The vacuum chamber main body 11 accommodates the substrate W such as a semiconductor wafer. A loading/unloading port 13 for loading or unloading the substrate W is formed on a side wall of the vacuum chamber main body 11. The loading/unloading port 13 is opened and closed by a gate valve 14. An exhaust port 15 is formed on a bottom wall of the vacuum chamber main body 11. The exhaust port 15 is connected to the exhaust device 60. The lid 12 is made of a metal material such as aluminum, for example, and is disposed so as to block the upper opening of the vacuum chamber main body 11. A space between the vacuum chamber main body 11 and the lid 12 is hermetically sealed with a sealing member (not shown).

The placing section 20 is disposed in the vacuum chamber 10. The placing section 20 includes a stage 21 on which the substrate W is placed. The stage 21 has a substrate placing surface on which the substrate W is placed in a central region of its upper surface. Further, the stage 21 has an annular member placing surface on which an annular member 25 is placed in an outer peripheral annular region radially outside the substrate placing surface on its upper surface. The substrate placing surface is formed at a position higher than the annular member placing surface. The stage 21 is made of, for example, a dielectric material such as ceramics or a metal material such as aluminum, stainless steel or nickel, and a heater 22 for heating the substrate W is provided inside. The heater 22 is powered by a heater power supply 23 to generate heat. By controlling the output of the heater 22 according to a temperature signal from a thermocouple (not shown) provided near the upper surface of the stage 21, the substrate W is controlled to a predetermined temperature. The stage 21 is provided with a plurality (e.g., three) of through holes 24 passing through the stage 21. Substrate lift pins 51, which will be described later, are disposed in the through holes 24.

The placing section 20 also includes an annular member 25. The annular member 25 is formed of a metal material such as stainless steel or titanium, is a member having a substantially annular shape, and is disposed on the annular member placing surface provided at an outer periphery of the substrate placing surface. The annular member 25 is a member for forming a gas flow path with the partition member 30 to be described later, and for setting a conductance to be constant in the circumferential direction of the substrate W.

An upper surface of the annular member 25 may be formed at a position higher than the substrate placing surface of the stage 21. In this configuration, an inner peripheral surface of the annular member 25 is disposed at a position higher than the substrate placing surface of the stage 21. As a result, when the substrate W placed on the substrate placing surface is displaced in the horizontal direction, a side surface of the substrate W comes into contact with the inner peripheral surface of the annular member 25. In this manner, the annular member 25 functions as a guide member that limits the displacement of the substrate W placed on the substrate placing surface and guides the position of the substrate W.

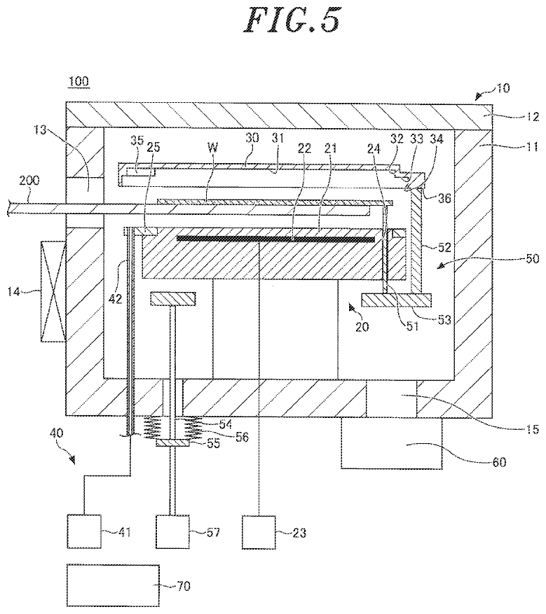

The partition member 30 is made of a heat-resistant material, such as stainless steel or titanium, and is a member which forms a gas processing space, which will be described later, between itself and the substrate placing surface of the stage 21 by partitioning a part of an internal space of the vacuum chamber 10. The partition member 30 is disposed to cover the placing section 20 and the substrate W placed on the placing section 20, thereby forming the gas processing space to which an inert gas is supplied between the placing section 20 and the partition member 30. Further, the partition member 30 is configured to be vertically movable by the vertical driving mechanism 50 described later. That is, the partition member 30 is configured to be movable between a closed position and an open position. As shown in FIG. 1, the closed position is a position (also referred to as a lowered position) in which the partition member 30 is disposed to cover the placing section 20 and the substrate W placed on the placing section 20 to form the gas processing space. As shown in FIG. 5 to be described later, the open position is a position (also referred to as a raised position) in which the partition member 30 is raised so that the substrate W can be transferred between the partition member 30 and the placing section 20.

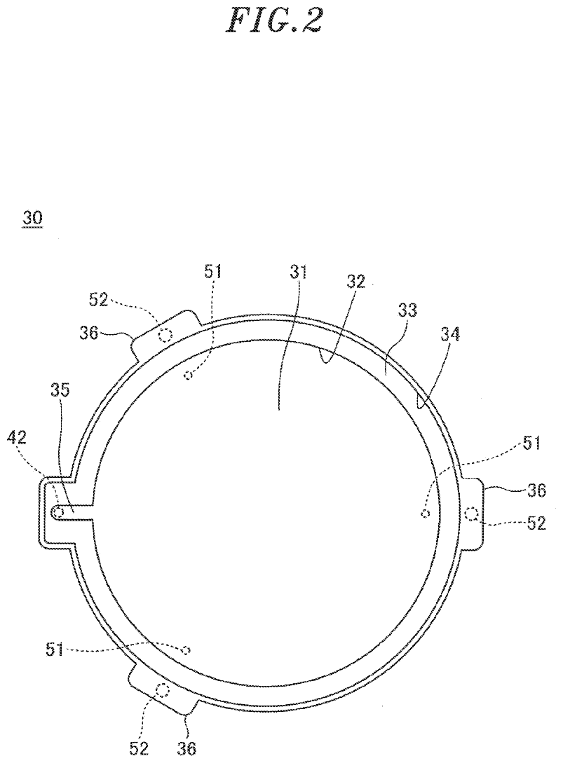

FIG. 2 is an example of a bottom view of the partition member 30. In FIG. 2, the positions of a gas supply pipe 42, the substrate lift pins 51, and partition member lift pins 52, which will be described later, are projected onto the partition member 30 by dotted lines.

The partition member 30 has a top surface 31, a first cylindrical surface 32, an annular surface 33, a second cylindrical surface 34, a gas supply channel 35, and a contact portion 36.

The top surface 31 is a substantially circular plane facing an upper surface of the substrate W placed on the stage 21. At the closed position (see FIG. 1), the top surface 31 is disposed at a position higher than the upper surface of the substrate W.

The first cylindrical surface 32 is a cylindrical surface disposed radially outside an outer peripheral surface of the substrate W placed on the stage 21. The first cylindrical surface 32 has an upper end connected to the top surface 31 and a lower end connected to the annular surface 33. As a result, a columnar gas processing space is formed, an upper surface of which is defined by the top surface 31, a lower surface of which is defined by the substrate placing surface of the stage 21, and an outer peripheral surface of which is defined by the first cylindrical surface 32. The substrate W is disposed in the gas processing space. Further, a space (gap) through which gas can flow is formed between the first cylindrical surface 32 and the outer peripheral surface of the substrate W at the closed position (see FIG. 1).

The annular surface 33 is a substantially annular flat surface facing the upper surface of the annular member 25 disposed on the stage 21. At the closed position (see FIG. 1), the annular surface 33 is disposed at a position higher than the upper surface of the substrate W placed on the annular member 25, and a space (gap) through which gas can flow is formed between the annular surface 33 and the upper surface of the annular member 25.

The second cylindrical surface 34 is a cylindrical surface disposed radially outside an outer peripheral surface of the annular member 25 disposed on the stage 21. The second cylindrical surface 34 is connected to the annular surface 33 at its upper end. At the closed position (see FIG. 1), a space (gap) through which gas can flow is formed between the annular surface 33 and the outer peripheral surface of the annular member 25.

The gas supply channel 35 is formed so as to communicate with the gas processing space from a position corresponding to a discharge port of the gas supply pipe 42, which will be described later. Thereby, the gas discharged from the gas supply pipe 42 is supplied to the gas processing space through the gas supply channel 35.

In other words, a rear surface of the partition member 30 has a first recess (first concave portion) forming the top surface 31 and the first cylindrical surface 32, a second recess (second concave portion) forming the annular surface 33 and the second cylindrical surface 34 and communicating with the first recess, and a third recess (third concave portion) forming the gas supply channel 35 and communicating with the first recess. The first recess forms the gas processing space between itself and the substrate placing surface of the stage 21 when the partition member 30 is placed at the closed position. The second recess forms an exhaust channel communicating with the gas processing space between itself and the annular member 25 when the partition member 30 is placed at the closed position. The width of the exhaust channel is, for example, 2 mm or less. The third recess forms a supply channel communicating the discharge port of the gas supply pipe 42 and the gas processing space when the partition member 30 is placed at the closed position.

The top surface 31, the first cylindrical surface 32, the annular surface 33, the second cylindrical surface 34, and the gas supply channel 35 are blasted surfaces or blasted and thermally sprayed surfaces. That is, surfaces (the top surface 31 and the first cylindrical surface 32) of the first recess of the partition member 30 forming the gas processing space are blasted surfaces or blasted and thermally sprayed surfaces. Further, surfaces (the annular surface 33 and the second cylindrical surface 34) of the second recess of the partition member 30 forming the exhaust channel from the gas processing space are blasted surfaces or blasted and thermally sprayed surfaces. Further, surface (the gas supply channel of the third recess of the partition member 30 forming the supply channel to the gas processing space is a blasted surface or a blasted and thermally sprayed surface.

Blasting promotes adsorption of the sublimated object to be removed. In blasting, the surface roughness is preferably, for example, 2.0 μm or more and 10 μm or less in terms of arithmetic mean roughness Ra.

Thermal spraying suppresses peeling of the object to be removed adsorbed on a surface of the partition member 30. As thermal spraying, aluminum thermal spraying, alumina thermal spraying, yttria thermal spraying or the like is used. In thermal spraying, the surface roughness is preferably, for example, 15 μm or more and 30 μm or less in terms of arithmetic mean roughness Ra.

The contact portion 36 contacts the partition member lift pins 52 when the partition member lift pins 52, described later, are raised.

Returning to FIG. 1, the gas supply 40 supplies an inert gas to the gas processing space. For example, argon (Ar) gas or nitrogen (N₂) gas can be used as the inert gas. The gas supply 40 includes a gas supply source 41 and the gas supply pipe 42. The gas supply source 41 supplies the inert gas to the gas processing space through the gas supply pipe 42 and the gas supply channel 35. The gas supply pipe 42 penetrates the vacuum chamber main body 11 and is connected to the upper surface of the annular member 25 so as to have the discharge port for discharging gas.

The vertical driving mechanism 50 drives the partition member 30 in the vertical direction. The vertical driving mechanism 50 places the substrate W on the placing surface of the stage 21 and lifts the substrate W from the placing surface of the stage 21. The vertical driving mechanism 50 includes the substrate lift pins 51, the partition member lift pins 52, a support plate 53, an elevating shaft 54, a collar portion 55, a bellows 56, and a driving device 57.

A plurality (for example, three) of substrate lift pins 51 are provided and disposed in the through holes 24 of the stage 21. The material of the substrate lift pins 51 may be, for example, a metallic material such as titanium. A lower end of the substrate lift pins 51 is fixed to the support plate 53.

A plurality (for example, three) of partition member lift pins 52 are provided and disposed radially outwardly of the stage 21. The material of the partition member lift pins 52 may be, for example, ceramic such as alumina (Al₂O₃). A lower end of the partition member lift pins 52 is fixed to the support plate 53.

The support plate 53 is formed in a substantially annular shape, for example. The support plate 53 is connected to the driving device 57 provided outside the vacuum chamber main body 11 through the elevating shaft 54 penetrating the bottom wall of the vacuum chamber main body 11. The collar portion 55 is attached to the elevating shaft 54 below the vacuum chamber main body 11. The bellows 56 is provided between the bottom wall of the vacuum chamber main body 11 and the collar portion 55. The bellows 56 separates the atmosphere inside the vacuum chamber main body 11 from the outside air, and expands and contracts as the support plate 53 moves up and down. The driving device 57 vertically drives the substrate lift pins 51 and the partition member lift pins 52 by vertically driving the support plate 53 via a driving shaft.

Although the vertical driving mechanism 50 has been described as a configuration in which the substrate lift pins 51 and the partition member lift pins 52 are integrally raised and lowered by one driving device 57, it is not limited thereto. For example, the vertical driving mechanism 50 may be configured to independently drive the substrate lift pins 51 and the partition member lift pins 52. Further, the configuration for driving the partition member 30 up and down is not limited to the lift pins, and may be a configuration in which a driving shaft connected to the partition member 30 is driven by a driving device.

The exhaust device 60 consists of, for example, a turbomolecular pump, a dry pump, or the like, and evacuates the interior of the vacuum chamber 10 through the exhaust port 15.

The controller 70 is, for example, a computer and includes a central processing unit (CPU), a random access memory (RAM), a read only memory (ROM), an auxiliary storage device, and the like. The CPU operates based on programs stored in the ROM or the auxiliary storage device, and controls the operation of the vacuum heat treatment apparatus 100. The controller 70 may be provided inside or outside the vacuum heat treatment apparatus 100. When the controller 70 is provided outside the vacuum heat treatment apparatus 100, the controller 70 controls the operation of the vacuum heat treatment apparatus 100 via communication means such as wired or wireless communication.

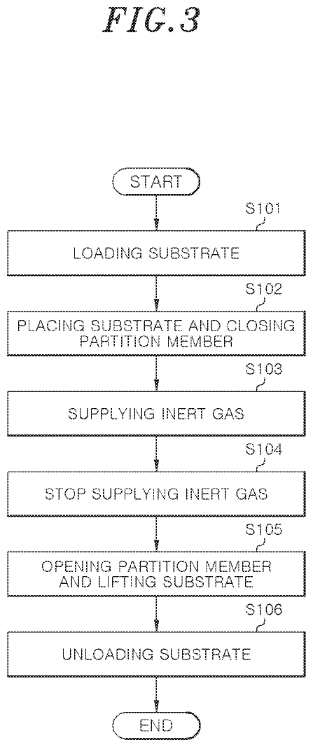

Next, an example of the operation of the vacuum heat treatment apparatus 100 will be described with reference to FIG. 3. FIG. 3 is an example of a flow chart showing the operation of the vacuum heat treatment apparatus 100.

Prior to starting the flow, the controller 70 controls the exhaust device 60 to create a desired vacuum atmosphere in the vacuum chamber 10. Further, the controller 70 controls the heater power supply 23 to cause the heater 22 to generate heat, thereby raising the temperature of the stage 21 to a desired temperature.

In step S101, the substrate W is loaded. The controller 70 controls the vertical driving mechanism 50 to place the partition member 30 at the open position (see FIG. 5 described later), and the substrate lift pins 51 protrude from the placing surface of the stage 21. Next, the controller 70 opens the gate valve 14 and controls a transfer arm 200 (see FIG. 5 described later) to transfer the substrate W held by the transfer arm 200 into the vacuum chamber 10 through the loading/unloading port 13 and place it on the substrate lift pins 51. Then, when the transfer arm 200 retracts from the loading/unloading port 13, the controller 70 closes the gate valve 14.

In step S102, the substrate W is placed on the placing section 20, and the partition member 30 is closed. Here, the controller 70 controls the driving device 57 to lower the substrate lift pins 51 and the partition member lift pins 52. Thereby, the substrate W placed on the substrate lift pins 51 is placed on the placing surface of the stage 21. Further, the partition member 30 moves to the closed position (see FIG. 1). Thereby, the gas processing space is formed and the substrate W is disposed in the gas processing space.

In step S103, the controller 70 controls the gas supply 40 to supply the inert gas to the gas processing space. The inert gas supplied from the gas supply source 41 is supplied to the gas processing space through the gas supply pipe 42 and the gas supply channel 35. Here, the partition member 30 placed at the closed position separates the gas processing space from other spaces in the internal space of the vacuum chamber 10. Therefore, the volume of the gas processing space is made smaller than the volume of the internal space of the vacuum chamber 10. Therefore, the inside of the gas processing space is rapidly pressurized by the inert gas supplied from the gas supply source 41. As a result, the time required to pressurize the inside of the gas processing space is shortened compared to the case where the entire inside of the vacuum chamber 10 is pressurized, thereby improving the throughput of the vacuum heat treatment apparatus 100. In addition, the consumption of the inert gas can be reduced.

The substrate W placed on the stage 21 is heated by the heater 22. As a result, the substrate W is brought to a predetermined high temperature state (for example, 100° C. to 450° C.), and the substrate W is exposed to an inert gas atmosphere of a predetermined high pressure (for example, 5 to 20 Torr), thereby sublimating the object to be removed formed on the substrate W (for example, a film formed in a previous step, moisture adsorbed on the substrate W, or the like). Due to the pressure difference between the gas processing space and the internal space of the vacuum chamber 10, the used inert gas and the sublimated object to be removed pass through the gap between the first cylindrical surface 32 and the outer peripheral surface of the substrate W, the gap between the annular surface 33 and the upper surface of the annular member 25, and the gap between the annular surface 33 and the outer peripheral surface of the annular member 25, and are exhausted into the internal space of the vacuum chamber 10. Further, the used inert gas and the sublimated object to be removed are exhausted from the vacuum chamber 10 by the exhaust device 60.

Here, since an inner surface of the partition member 30 is subjected to blasting or the like, the object to be removed sublimated from the substrate W adheres to the inner surface of the partition member 30. Thus, it is possible to prevent the sublimated object to be removed from widely diffusing on an inner wall surface of the vacuum chamber 10. In other words, the object to be removed adhering to the inner wall surface of the vacuum chamber 10 can be reduced, the cleaning intervals of the vacuum chamber 10 can be extended, the downtime of the vacuum heat treatment apparatus 100 can be reduced, and the throughput of the vacuum heat treatment apparatus 100 can be improved.

In step S104, the controller 70 controls the gas supply 40 to stop supplying the inert gas to the gas processing space.

In step S105, the partition member 30 is opened and the substrate W is lifted from the placing section 20. Here, the controller 70 controls the driving device 57 to raise the substrate lift pins 51 and the partition member lift pins 52.

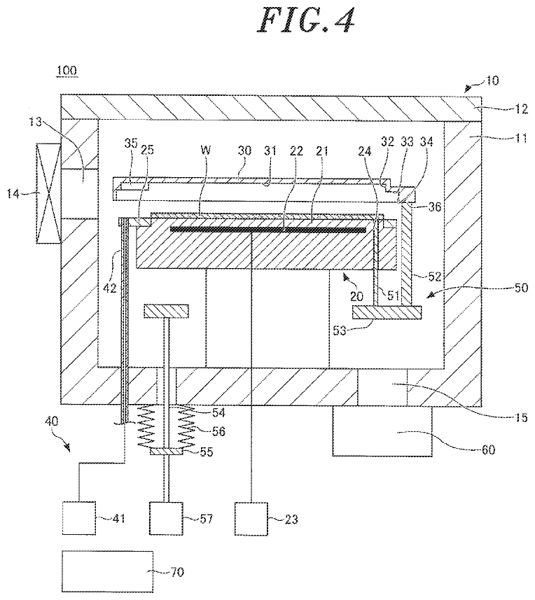

FIG. 4 is an example of a cross-sectional view of the vacuum heat treatment apparatus 100 while the substrate lift pins 51 and the partition member lift pins 52 are being raised. By raising the support plate 53, as shown in FIG. 4, before the substrate lift pins 51 come into contact with a rear surface of the substrate W, the partition member lift pins 52 come into contact with the contact portion 36 of the partition member 30, and the partition member 30 begins to rise.

FIG. 5 is an example of a cross-sectional view of the vacuum heat treatment apparatus 100 after the substrate lift pins 51 and the partition member lift pins 52 have finished rising. As the support plate 53 is further raised, as shown in FIG. 5, the substrate lift pins 51 come into contact with the rear surface of the substrate W and lift the substrate W from the placing surface of the stage 21. The partition member 30 continues to rise and stops at the open position.

In step S106, the substrate W is unloaded. The controller 70 opens the gate valve 14 and controls the transfer arm 200 to enter the vacuum chamber 10 through the loading/unloading port 13 and receive the substrate W placed on the substrate lift pins 51. Then, when the transfer arm 200 holding the substrate W is withdrawn from the loading/unloading port 13, the controller 70 closes the gate valve 14.

Thereafter, the processing returns to step S101, and the next substrate W is processed in the same manner.

As described above, in the vacuum heat treatment apparatus 100, when the partition member 30 is placed at the closed position (see FIG. 1) by the vertical driving mechanism 50, it partitions a part of the internal space of the vacuum chamber 10 to form the gas processing space between itself and the substrate placing surface of the stage 21. Then, the gas supply 40 supplies the inert gas to the gas processing space to expose the substrate W disposed in the gas processing space to an inert gas atmosphere of high pressure (for example, 5 to 20 Torr). In this way, by reducing the space to which the gas supply 40 supplies the inert gas, the time required to pressurize the inside of the gas processing space is shortened and the throughput of the vacuum heat treatment apparatus 100 is improved. In addition, the consumption of the inert gas can be reduced.

Since the inner surface of the partition member 30 is subjected to blasting, the object to be removed sublimated from the substrate W is adsorbed near the substrate W. As a result, the object to be removed adhering to the inner wall surface of the vacuum chamber 10 can be reduced, the cleaning intervals of the vacuum chamber 10 can be extended, the downtime of the vacuum heat treatment apparatus 100 can be reduced, and the throughput of the vacuum heat treatment apparatus 100 can be improved.

The present disclosure is not limited to the configuration described in the above embodiments, and other components can be combined with the configuration described in the above embodiments. The above embodiments can be modified without departing from the scope of the present disclosure, and can be appropriately determined according to the form of the application.

1. A vacuum heat treatment apparatus comprising:
a vacuum chamber;
a stage disposed in the vacuum chamber and having a substrate placing surface on which a substrate is placed;
a heater provided in the stage;
a partition member configured to partition a part of an internal space of the vacuum chamber to form a gas processing space between itself and the substrate placing surface of the stage; and
a gas supply configured to supply gas to the gas processing space.

2. The vacuum heat treatment apparatus of claim 1, further comprising:
a vertical driving mechanism configured to drive the partition member in a vertical direction.

3. The vacuum heat treatment apparatus of claim 2, wherein the vertical driving mechanism includes:
substrate lift pins;
partition member lift pins;
a support plate to which the substrate lift pins and the partition member lift pins are fixed; and
a driving device configured to drive the support plate.

4. The vacuum heat treatment apparatus of claim 1, wherein the partition member has a first recess forming the gas processing space between the partition member and the substrate placing surface of the stage.

5. The vacuum heat treatment apparatus of claim 4, wherein the stage has an annular member disposed on an outer peripheral side of the substrate placing surface, and
the partition member further has a second recess forming an exhaust channel communicating with the gas processing space between the partition member and the annular member.

6. The vacuum heat treatment apparatus of claim 5, wherein the gas supply has a discharge port configured to discharge gas onto an upper surface of the annular member, and
the partition member further has a third recess communicating with the first recess from a position corresponding to the discharge port.

7. The vacuum heat treatment apparatus of claim 4, wherein a surface of the first recess is a treated surface which has been subjected to blasting.

8. The vacuum heat treatment apparatus of claim 7, wherein the surface of the first recess is a treated surface which has been subjected to blasting and thermal spraying.

9. The vacuum heat treatment apparatus of claim 5, wherein surfaces of the first recess and the second recess are treated surfaces which have been subjected to blasting.

10. The vacuum heat treatment apparatus of claim 9, wherein the surfaces of the first recess and the second recess are treated surfaces which have been subjected to blasting and thermal spraying.

11. The vacuum heat treatment apparatus of claim 6, wherein surfaces of the first recess, the second recess, and the third recess are treated surfaces which have been subjected to blasting.

12. The vacuum heat treatment apparatus of claim 11, wherein the surfaces of the first recess, the second recess, and the third recess are treated surfaces which have been subjected to blasting and thermal spraying.
